(19) United States
(12) Patent Application Publication
(10) Pub. No.: US 2026/0190376 A1
(43) Pub. Date: Jul. 2, 2026

(54) POWER DEVICE AND MANUFACTURING METHOD THEREOF

(71) Applicant: INNOSCIENCE (SUZHOU) SEMICONDUCTOR CO., LTD., Suzhou (CN)

(72) Inventors: Jie Zhao, Suzhou (CN); Fu Chen, Suzhou (CN); Yan Liu, Suzhou (CN)

(21) Appl. No.: 19/416,152

(22) Filed: Dec. 11, 2025

Related U.S. Application Data
(63) Continuation of application No. PCT/CN2025/108367, filed on Jul. 14, 2025.

(30) Foreign Application Priority Data
Dec. 30, 2024 (CN) 202411959341.1

(51) Int. Cl. H10D 30/47; H10D 30/01; H10D 62/10; H10D 62/824

(52) U.S. Cl. CPC H10D 30/475; H10D 30/015; H10D 62/102; H10D 62/126; H10D 62/824

(57) ABSTRACT

Provided are a power device and a manufacturing method thereof. The power device includes an epitaxial structure, a doped nitride semiconductor layer, a passivation layer, a source and a drain. The epitaxial structure includes an active region and an edge region, where the edge region surrounds the active region and includes a first edge region and a second edge region, the first edge region of the epitaxial structure is an electrically isolated region, and a conductive channel is provided at an interface between the channel layer and the barrier layer in the second edge region. The doped nitride semiconductor layer includes a first region and a second region connected to each other, and a distance between an edge of the conductive channel of the second edge region and a vertical projection of an edge of the second region on the barrier layer is greater than a first preset value.

### CROSS-REFERENCE TO RELATED APPLICATIONS

This is a continuation of International Patent Application No. PCT/CN2025/108367, filed on Jul. 14, 2025, which claims priority to Chinese Patent Application No. 202411959341.1 filed with the China National Intellectual Property Administration (CNIPA) on Dec. 30, 2024, the disclosures of which are incorporated herein by reference in their entireties.

### TECHNICAL FIELD

The present application relates to the technical field of semiconductors and, in particular, to a power device and a manufacturing method thereof.

### BACKGROUND

In the process of manufacturing a power device, problems such as gate leakage and reduced device reliability may occur.

### SUMMARY

The present application provides a power device and a manufacturing method thereof, thereby reducing gate leakage and improving device reliability.

According to an aspect of the present application, a power device is provided and includes an epitaxial structure, a doped nitride semiconductor layer, a passivation layer, a source, and a drain.

The epitaxial structure includes a substrate, a buffer layer, a channel layer and a barrier layer that are stacked in sequence, the epitaxial structure includes an active region and an edge region, the edge region surrounds the active region and includes a first edge region and a second edge region, the first edge region of the epitaxial structure is an electrically isolated region, and a conductive channel is provided at an interface between the channel layer and the barrier layer in the second edge region.

The doped nitride semiconductor layer is located on a side of the barrier layer facing away from the substrate and includes a first region and a second region connected to each other, the first region covers a portion of the active region of the epitaxial structure, a vertical projection of the second region on the barrier layer is located in the conductive channel of the second edge region, and a distance between an edge of the conductive channel of the second edge region and a vertical projection of an edge of the second region on the barrier layer is greater than a first preset value.

The passivation layer is located on a side of the doped nitride semiconductor layer facing away from the epitaxial structure and includes a first trench and a second trench, a vertical projection of the first trench on the epitaxial structure overlaps the active region, and a vertical projection of the second trench on the epitaxial structure overlaps the active region.

The source is located in the first trench, and the drain is located in the second trench.

In one or more examples, the first preset value is greater than 25 nm.

In one or more examples, a shape of a vertical projection of the doped nitride semiconductor layer on the epitaxial structure is a ring.

The vertical projection of the first trench on the epitaxial structure is located within a central region of the ring, and the vertical projection of the second trench on the epitaxial structure is located at a side of the ring.

In one or more examples, the power device further includes a gate.

The gate is located on the side of the doped nitride semiconductor layer facing away from the epitaxial structure and at least covers a portion of the doped nitride semiconductor layer.

In one or more examples, the doped nitride semiconductor layer includes a p-type GaN layer or a p-type AlGaN layer.

According to an aspect of the present application, a manufacturing method of a power device is provided and including the following:

An epitaxial structure is formed. The epitaxial structure includes a substrate, a buffer layer, a channel layer, and a barrier layer that are stacked in sequence, the epitaxial structure includes an active region and an edge region, and the edge region surrounds the active region and includes a first edge region and a second edge region.

A doped nitride semiconductor layer is formed on a side of the barrier layer facing away from the substrate. The doped nitride semiconductor layer includes a first region and a second region connected to each other, the first region covers a portion of the active region of the epitaxial structure, and a vertical projection of the second region on the barrier layer is located in the second edge region.

A passivation layer is formed on a side of the doped nitride semiconductor layer facing away from the epitaxial structure. The passivation layer includes a first trench and a second trench, a vertical projection of the first trench on the epitaxial structure overlaps the active region, and a vertical projection of the second trench on the epitaxial structure overlaps the active region.

A source is formed in the first trench, and a drain is formed in the second trench.

A protective layer is formed on a side of the passivation layer facing away from the epitaxial structure. A vertical projection of the protective layer on the epitaxial structure covers the active region of the epitaxial structure, a vertical projection of the protective layer on the edge region of the epitaxial structure coincides with the second edge region, and a distance between a vertical projection of an edge of the second region of the doped nitride semiconductor layer on the epitaxial structure and a vertical projection of an edge of the protective layer on the epitaxial structure is greater than a second preset value.

The epitaxial structure is processed such that the first edge region of the epitaxial structure is an electrically isolated region and a distance between an edge of a conductive channel of the second edge region and a vertical projection of the edge of the second region of the doped nitride semiconductor layer on the barrier layer is greater than a first preset value.

The protective layer is removed.

In one or more examples, the first preset value is greater than 25 nm, and the second preset value is greater than 25 nm.

In one or more examples, forming the protective layer on the side of the passivation layer facing away from the epitaxial structure includes the following:

A protective material layer is formed on the side of the passivation layer facing away from the epitaxial structure.

Patterned etching is performed on the protective material layer to form the protective layer.

In one or more examples, forming the doped nitride semiconductor layer on the side of the barrier layer facing away from the substrate includes the following:

A doped nitride semiconductor material layer is formed on one side of the epitaxial structure.

Patterned etching is performed on the doped nitride semiconductor material layer to form the doped nitride semiconductor layer. A shape of a vertical projection of the doped nitride semiconductor layer on the epitaxial structure is a ring.

In one or more examples, forming the passivation layer on the side of the doped nitride semiconductor layer facing away from the epitaxial structure includes the following:

The passivation layer is formed on the side of the doped nitride semiconductor layer facing away from the epitaxial structure. The passivation layer covers the doped nitride semiconductor layer and a portion of the epitaxial structure which is not covered by the doped nitride semiconductor layer.

The passivation layer is etched to form the first trench and the second trench. The vertical projection of the first trench on the epitaxial structure is located within a central region of the ring, and the vertical projection of the second trench on the epitaxial structure is located at a side of the ring.

In one or more examples, after forming the doped nitride semiconductor layer on the side of the barrier layer facing away from the substrate, the method further includes forming a gate on the side of the doped nitride semiconductor layer facing away from the epitaxial structure. The gate covers at least a portion of the doped nitride semiconductor layer.

In one or more examples, processing the epitaxial structure such that the first edge region of the epitaxial structure is the electrically isolated region includes performing ion bombardment on the epitaxial structure such that the first edge region of the epitaxial structure is the electrically isolated region.

In one or more examples, an ion source for the ion bombardment is at least one of nitrogen, fluorine, oxygen, or argon.

The power device provided in the technical solution of the example of the present application includes the epitaxial structure, the doped nitride semiconductor layer, the passivation layer, the source and the drain. The epitaxial structure includes the substrate, the buffer layer, the channel layer and the barrier layer that are stacked in sequence, and the epitaxial structure includes the active region and the edge region, where the edge region surrounds the active region and includes the first edge region and the second edge region, the first edge region of the epitaxial structure is the electrically isolated region, and the conductive channel is provided at the interface between the channel layer and the barrier layer in the second edge region. The doped nitride semiconductor layer is located on the side of the barrier layer facing away from the substrate and includes the first region and the second region that are connected to each other, where the first region covers a portion of the active region of the epitaxial structure, the vertical projection of the second region on the barrier layer is located in the conductive channel of the second edge region, and the distance between the edge of the conductive channel of the second edge region and the vertical projection of the edge of the second region on the barrier layer is greater than the first preset value. The passivation layer is located on the side of the doped nitride semiconductor layer facing away from the epitaxial structure and includes the first trench and the second trench, where the vertical projection of the first trench on the epitaxial structure overlaps the active region, and the vertical projection of the second trench on the epitaxial structure overlaps the active region. The source is located in the first trench, and the drain is located in the second trench. In the examples of the present application, the vertical projection of the second region on the barrier layer is located in the conductive channel of the second edge region, and the distance between the vertical projection of the edge of the second region on the barrier layer and the edge of the conductive channel of the second edge region is greater than the first preset value. In this manner, the doped nitride semiconductor layer can be prevented from being damaged when the electrically isolated region is formed in the first edge region, thereby reducing the gate leakage and improving the device reliability.

It is to be understood that the content described in this part is neither intended to identify key or important features of the examples of the present application nor intended to limit the scope of the present application. Other features of the present application are apparent from the description provided hereinafter.

### BRIEF DESCRIPTION OF DRAWINGS

To illustrate technical solutions in examples of the present application more clearly, drawings used in the description of the examples are briefly described below. Apparently, the drawings described below illustrate part of the examples of the present application. Those of ordinary skill in the art may further obtain other drawings based on these drawings on the premise that no creative work is done.

FIG. 1 is a schematic diagram illustrating the structure of a power device according to an example of the present application.

FIG. 2 is a section view taken along a section line A1A2 of FIG. 1.

FIG. 3 is a flowchart of a manufacturing method of a power device according to an example of the present application.

FIGS. 4 to 10 are schematic diagrams illustrating intermediate structures of a power device according to an example of the present application.

### DETAILED DESCRIPTION

For a better understanding of the solution of the present application by those skilled in the art, the technical solutions in examples of the present application are described clearly and completely hereinafter in conjunction with the drawings in the examples of the present application. Apparently, the examples described hereinafter are part, not all, of examples of the present application. Based on the examples of the present application, all other examples obtained by those of ordinary skill in the art on the premise that no creative work is done are within the scope of the present application.

It should be noted that the terms “first”, “second” and the like described in the present application are used to distinguish between similar objects and are not necessarily used to describe a particular order or sequence. It is to be understood that data used in this manner are interchangeable where appropriate so that the examples of the present application described herein can be implemented in an order not illustrated or described herein. Additionally, terms “include”, “have”, and any variations thereof are intended to encompass a non-exclusive inclusion. For example, a process, method, system, product, or device that includes a series of steps or units not only includes the expressly listed steps or units but may also include other steps or units that are not expressly listed or are inherent to such process, method, product, or device.

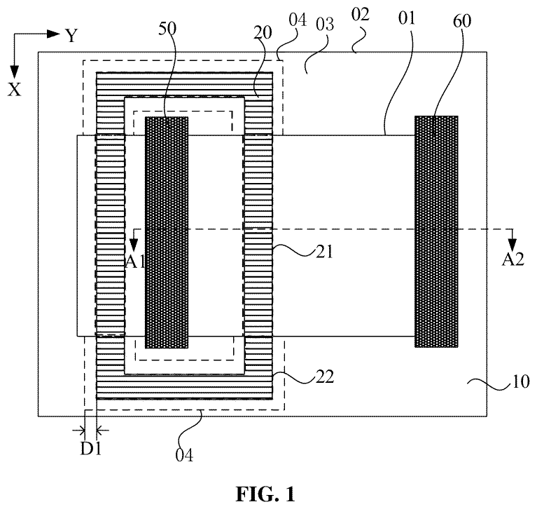

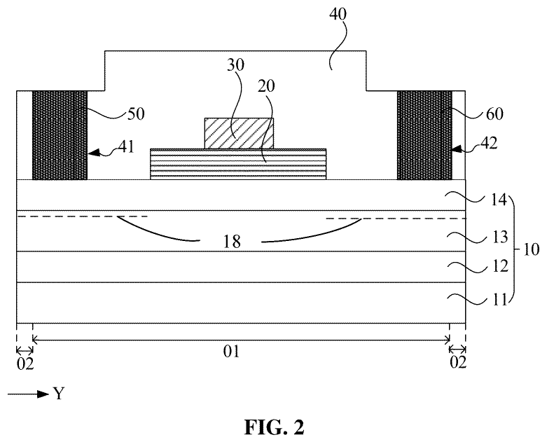

Examples of the present application provide a power device. FIG. 1 is a schematic diagram illustrating the structure of a power device according to an example of the present application. FIG. 2 is a section view taken along a section line A1A2 of FIG. 1. The power device includes an epitaxial structure 10, a doped nitride semiconductor layer 20, a passivation layer 40, a source 50 and a drain 60.

The epitaxial structure 10 includes a substrate 11, a buffer layer 12, a channel layer 13, and a barrier layer 14 that are stacked in sequence, and includes an active region 01 and an edge region 02. The edge region 02 surrounds the active region 01 and includes a first edge region 03 and a second edge region 04, the first edge region 03 of the epitaxial structure 10 is an electrical isolation region, and a conductive channel 18 is provided at an interface between the channel layer 13 and the barrier layer 14 in the second edge region 04.

The doped nitride semiconductor layer 20 is located on a side of the barrier layer 14 facing away from the substrate 11 and includes a first region 21 and a second region 22 connected to each other, the first region 21 covers a portion of the active region 01 of the epitaxial structure 10, a vertical projection of the second region 22 on the barrier layer 14 is located in the conductive channel 18 of the second edge region 04, and a distance D1 between an edge of the conductive channel 18 of the second edge region 04 and a vertical projection of an edge of the second region 22 on the barrier layer 14 is greater than a first preset value. The passivation layer 40 is located on a side of the doped nitride semiconductor layer 20 facing away from the epitaxial structure 10 and includes a first trench 41 and a second trench 42, a vertical projection of the first trench 41 on the epitaxial structure 10 overlaps the active region 01, and a vertical projection of the second trench 42 on the epitaxial structure 10 overlaps the active region 01.

The source 50 is located in the first trench 41, and the drain 60 is located in the second trench 42.

The power device in the example of the present application may be a gallium nitride high-electron-mobility transistor (HEMT). The channel layer 13 may be a gallium nitride layer, and the barrier layer 14 may be an AlGaN layer. In the HEMT device, a two-dimensional electron gas may be formed at an interface where the channel layer 13 is in contact with the barrier layer 14 in the active region 01, and the conductive channel 18 may be formed; thus, the device can be turned on. The doped nitride semiconductor layer 20 includes a p-type GaN layer or a p-type AlGaN layer. The material of the passivation layer 40 may be silicon oxide or silicon nitride, and the passivation layer 40 is used for isolating the source 50, the drain 60 and the doped nitride semiconductor layer 20. The source 50 and the drain 60 are made of the same material and may both be made of a metal material. In a length direction X, if the doped nitride semiconductor layer 20 and the active region 01 have the same length dimension, since an effect of a process error exists in the process of manufacturing the power device, gate leakage occurs when the device is turned off, resulting in a decrease in device reliability. Therefore, the length dimension of the doped nitride semiconductor layer 20 needs to be greater than the length dimension of the active region 01, which can reduce the gate leakage and enables the doped nitride semiconductor layer 20 to change the distribution of electric field, improve a voltage withstand capability of the device and enhance the capability to control the current between the source and the drain of the device.

Specifically, to reduce the gate leakage, the length dimension of the doped nitride semiconductor layer 20 is set to be greater than the length dimension of the active region 01, a vertical projection of a region of the doped nitride semiconductor layer 20 (located outside the active region 01) on the epitaxial structure 10 coincides with the second edge region 04, and the conductive channel 18 exists at the interface between the channel layer 13 and the barrier layer 14 in the second edge region 04. Since no excess uncontrolled two-dimensional electron gas is required in the ineffective first edge region 03, electrons of the first edge region 03 need to be destroyed through ion bombardment so that the first edge region 03 has no conductive channel and the first edge region 03 is the electrically isolated region. If the vertical projection of the second region 22 on the barrier layer 14 coincides with the conductive channel 18 or the conductive channel 18 is located within the vertical projection of the second region 22 on the barrier layer 14, when ion bombardment is performed on the epitaxial structure 10, the second region 22 of the doped nitride semiconductor layer 20 may be damaged, which causes a failure in pinching off a channel below the doped nitride semiconductor layer 20 when the device is turned off, and further causes device leakage. Therefore, in the example of the present application, the vertical projection of the second region 22 on the barrier layer 14 is located in the conductive channel 18 of the second edge region 04, and the distance D1 between the vertical projection of the edge of the second region 22 on the barrier layer 14 and the edge of the conductive channel 18 of the second edge region 04 is greater than the first preset value. When the edge region 02 is processed, the second region 22 of the doped nitride semiconductor layer 20 is not damaged, thereby reducing the gate leakage and improving the device reliability.

The power device provided in the technical solution of the example of the present application includes the epitaxial structure 10, the doped nitride semiconductor layer 20, the passivation layer 40, the source 50 and the drain 60. The epitaxial structure 10 includes the substrate 11, the buffer layer 12, the channel layer 13, and the barrier layer 14 that are stacked in sequence, and includes the active region 01 and the edge region 02. The edge region 02 surrounds the active region 01 and includes the first edge region 03 and the second edge region 04, the first edge region 03 of the epitaxial structure 10 is the electrically isolated region, and the conductive channel 18 exists at the interface between the channel layer 13 and the barrier layer 14 in the second edge region 04. The doped nitride semiconductor layer 20 is located on the side of the barrier layer 14 facing away from the substrate 11 and includes the first region 21 and the second region 22 that are connected to each other. The first region 21 covers a portion of the active region 01 of the epitaxial structure 10, the vertical projection of the second region 22 on the barrier layer 14 is located in the conductive channel 18 of the second edge region 04, and the distance D1 between the edge of the conductive channel 18 of the second edge region 04 and the vertical projection of the edge of the second region 22 on the barrier layer 14 is greater than the first preset value. The passivation layer 40 is located on the side of the doped nitride semiconductor layer 20 facing away from the epitaxial structure 10 and includes the first trench 41 and the second trench 42. The vertical projection of the first trench 41 on the epitaxial structure 10 overlaps the active region 01, and the vertical projection of the second trench 42 on the epitaxial structure 10 overlaps the active region 01. The source 50 is located in the first trench 41, and the drain 60 is located in the second trench 42. In the example of the present application, the vertical projection of the second region 22 on the barrier layer 14 is located in the conductive channel 18 of the second edge region 04, and the distance D1 between the vertical projection of the edge of the second region 22 on the barrier layer 14 and the edge of the conductive channel 18 of the second edge region 04 is greater than the first preset value. In this manner, the doped nitride semiconductor layer 20 can be prevented from being damaged when the electrically isolated region is formed in the first edge region 03, thereby reducing the gate leakage and improving the device reliability.

In one or more examples, referring to FIG. 1, the first preset value is greater than 25 nm.

If the first preset value is less than or equal to 25 nm, the process is challenging, and if the distance between the vertical projection of the edge of the second region 22 on the barrier layer 14 and the edge of the conductive channel 18 of the second edge region 04 is too small, the second region 22 of the doped nitride semiconductor layer 20 may be damaged when ion bombardment is performed on the epitaxial structure 10, resulting in the device leakage. Therefore, the first preset value is set to be greater than 25 nm, and in the width direction Y of the doped nitride semiconductor layer 20, the width of the second edge region 04 is at least 50 nm greater than the width of the doped nitride semiconductor layer 20. When the edge region 02 is processed, the second region 22 of the doped nitride semiconductor layer 20 is not damaged, thereby reducing the gate leakage and improving the device reliability.

In one or more examples, referring to FIGS. 1 and 2, the shape of the vertical projection of the doped nitride semiconductor layer 20 on the epitaxial structure 10 is a ring; the vertical projection of the first trench 41 on the epitaxial structure 10 is located within a central region of the ring, and the vertical projection of the second trench 42 on the epitaxial structure 10 is located at a side of the ring.

The shape of the vertical projection of the doped nitride semiconductor layer 20 on the epitaxial structure 10 is the ring, and the ring-shaped nitride semiconductor layer 20 surrounds the source 50 so that concentration of the electric field can be alleviated, the voltage withstand capability of the device can be improved, the capability to control the channel can be enhanced and the device performance can be improved, thereby improving the device stability and reliability.

In one or more examples, referring to FIG. 2, the power device further includes a gate 30 located on the side of the doped nitride semiconductor layer 20 facing away from the epitaxial structure 10 and at least covering a portion of the doped nitride semiconductor layer 20.

The gate 30 is formed on the side of the doped nitride semiconductor layer 20 facing away from the epitaxial structure 10 and at least covers a portion of the doped nitride semiconductor layer 20 so that a vertical projection of the gate 30 on the epitaxial structure 10 is located within the vertical projection of the doped nitride semiconductor layer 20 on the epitaxial structure 10, thereby reducing the leakage of the gate 30 and improving the device reliability. Through the adjustment of a gate voltage, the doped nitride semiconductor layer 20 can change the distribution of the electric field of the two-dimensional electron gas in the conductive channel 18 to improve the voltage withstand capability of the device, and the electron concentration of the two-dimensional electron gas can be accurately controlled to enhance the capability of the device to control the current.

In one or more examples, the doped nitride semiconductor layer includes a p-type GaN layer or a p-type AlGaN layer.

The doped nitride semiconductor layer 20 includes the p-type GaN layer or the p-type AlGaN layer, and the p-type GaN layer or the p-type AlGaN layer can change the distribution of the electric field, improve the voltage withstand capability of the device and enhance the capability to control the current between the source 50 and the drain 60 of the device.

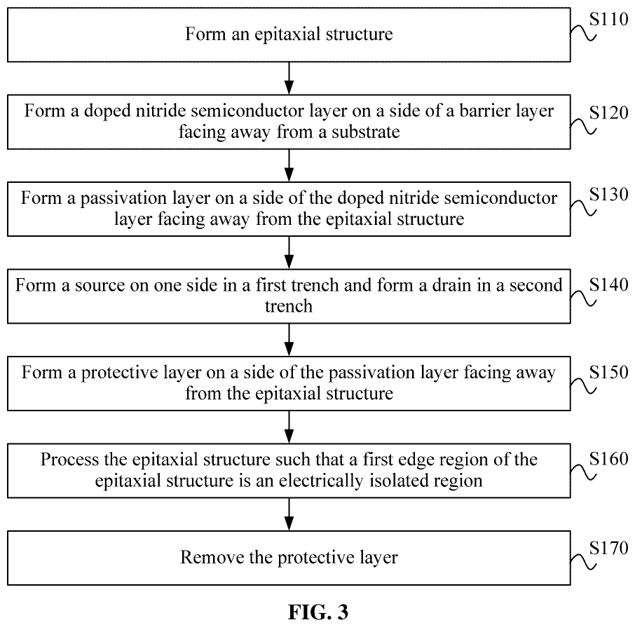

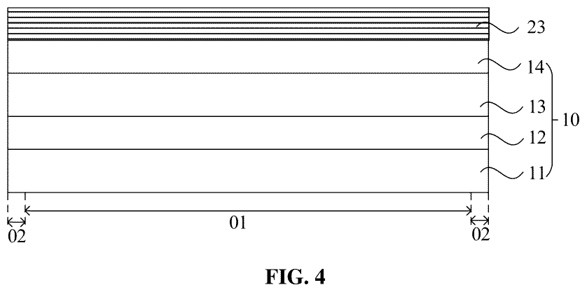

The examples of the present application provide a manufacturing method of a power device on the basis of the preceding examples, and the manufacturing method in the example of the present application is used for manufacturing the power device in any example of the present disclosure. FIG. 3 is a flowchart of a manufacturing method of a power device according to an example of the present application. FIGS. 4 to 10 are schematic diagrams illustrating intermediate structures of a power device according to an example of the present application. Referring to FIGS. 3 to 10, the manufacturing method includes the steps described below.

In S110, an epitaxial structure is formed. The epitaxial structure includes a substrate, a buffer layer, a channel layer and a barrier layer that are stacked in sequence, and the epitaxial structure includes an active region and an edge region, and the edge region surrounds the active region and includes a first edge region and a second edge region.

The power device in the examples of the present application may be a gallium nitride high-electron-mobility transistor (HEMT). Referring to FIG. 4, the buffer layer 12, the channel layer 13 and the barrier layer 14 are formed on the substrate 11 in sequence through a deposition process, thereby forming the epitaxial structure 10. The epitaxial structure 10 includes the active region 01 and the edge region 02, and the edge region 02 surrounds the active region 01. The channel layer 13 may be a gallium nitride layer, and the barrier layer 14 may be an AlGaN layer. In the HEMT device, a two-dimensional electron gas is formed at the interface where the channel layer 13 is in contact with the barrier layer 14 to form the conductive channel 18, thereby enabling the device to be turned on.

In S120, a doped nitride semiconductor layer is formed on the side of the barrier layer facing away from the substrate. The doped nitride semiconductor layer includes a first region and a second region that are connected to each other, the first region covers a portion of the active region of the epitaxial structure, and a vertical projection of the second region on the barrier layer is located in the second edge region.

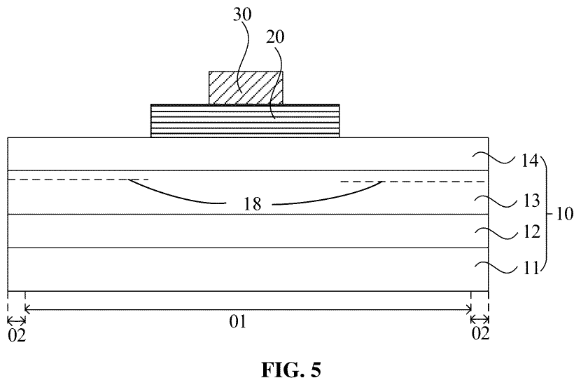

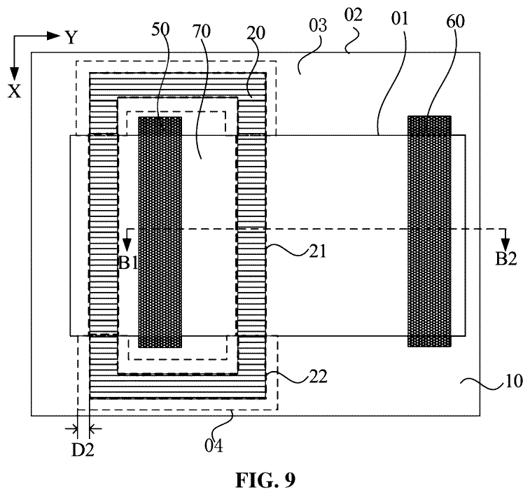

Referring to FIG. 4, a doped nitride semiconductor material layer 23 may be formed on the side of the barrier layer 14 facing away from the substrate 11. Referring to FIG. 5, patterned etching is performed on the doped nitride semiconductor material layer 23 to form the doped nitride semiconductor layer 20, and the doped nitride semiconductor layer 20 includes a p-type GaN layer or a p-type AlGaN layer. Referring to FIG. 9, the doped nitride semiconductor layer 20 includes the first region 21 and the second region 22 that are connected to each other, the first region 21 covers a portion of the active region 01 of the epitaxial structure 10, and the second region 22 covers a portion of the edge region 02 of the epitaxial structure 10. In the length direction X, if the doped nitride semiconductor layer 20 and the active region 01 have the same length dimension, due to an effect of a process error in the process of manufacturing the power device, the gate leakage occurs when the device is turned off, resulting in a decrease in the device reliability. Since no excess uncontrolled two-dimensional electron gas is required in the ineffective first edge region 03, the length dimension of the doped nitride semiconductor layer 20 needs to be greater than the length dimension of the active region 01, which can reduce the gate leakage and enables the doped nitride semiconductor layer 20 to change the distribution of the electric field, improve the voltage withstand capability of the device and enhance the capability to control the current between the source and the drain of the device.

In S130, a passivation layer is formed on the side of the doped nitride semiconductor layer facing away from the epitaxial structure. The passivation layer includes a first trench and a second trench, a vertical projection of the first trench on the epitaxial structure overlaps the active region, and a vertical projection of the second trench on the epitaxial structure overlaps the active region.

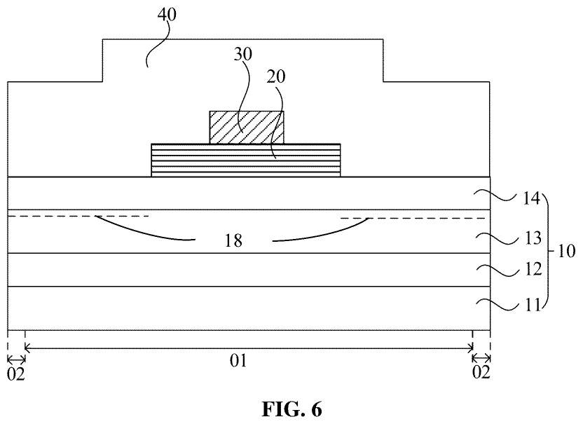

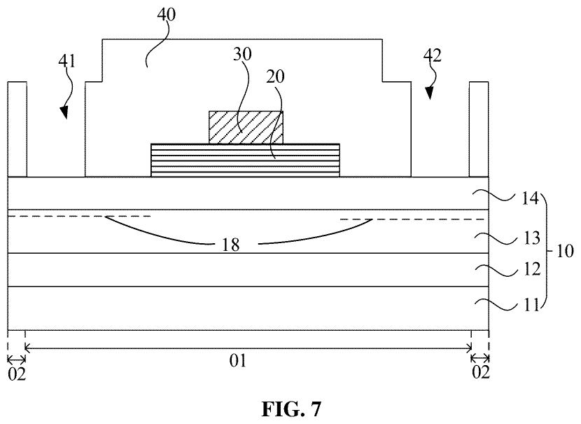

Referring to FIG. 6, the passivation layer 40 may be formed on the side of the doped nitride semiconductor layer 20 facing away from the epitaxial structure 10. Referring to FIG. 7, the passivation layer 40 is etched to form the first trench 41 and the second trench 42. The material of the passivation layer 40 may be silicon oxide or silicon nitride, and the passivation layer 40 is used for isolating the source, the drain and the doped nitride semiconductor layer 20.

In S140, a source is formed in the first trench, and a drain is formed in the second trench.

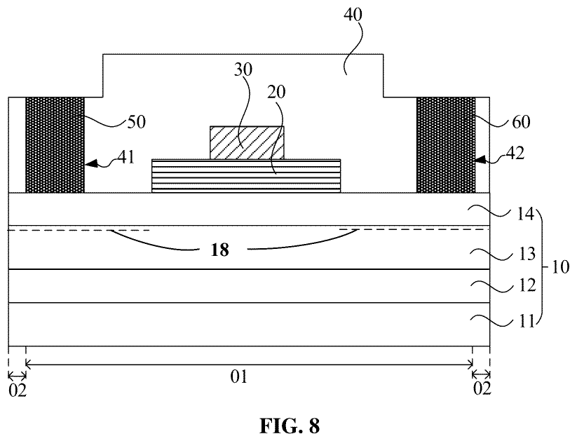

Referring to FIG. 8, the source 50 and the drain 60 are formed simultaneously, thereby simplifying process steps and saving process time. The source 50 and the drain 60 are made of the same material and may both be made of a metal material. The structure in FIG. 8 is different from that in FIG. 2. The first edge region in FIG. 2 is electrically isolated, and the electrically isolated region has not been formed in the first edge region in FIG. 8 yet.

In S150, a protective layer is formed on the side of the passivation layer facing away from the epitaxial structure. A vertical projection of the protective layer on the epitaxial structure covers the active region of the epitaxial structure, a vertical projection of the protective layer on the edge region of the epitaxial structure coincides with the second edge region, and a distance between a vertical projection of an edge of the second region of the doped nitride semiconductor layer on the epitaxial structure and a vertical projection of an edge of the protective layer on the epitaxial structure is greater than a second preset value.

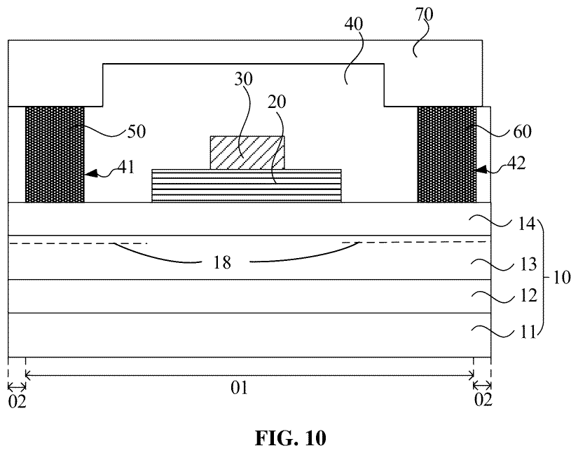

Referring to FIGS. 9 and 10, FIG. 9 is a schematic diagram illustrating an intermediate structure of a power device including a protective layer 70, and FIG. 10 is a section view taken along section line B1B2 in FIG. 9. The material of the protective layer 70 includes photoresist or metallic titanium, and the protective layer 70 is used for protecting the active region 01 and the doped nitride semiconductor layer 20. The protective layer 70 may be removed through wet etching in the subsequent process without affecting the passivation layer 40, and the photoresist and titanium processes are mature techniques.

Specifically, since the length dimension of the doped nitride semiconductor layer 20 is set to be greater than the length dimension of the active region 01, to reduce the gate leakage, electrons of the first edge region 03 need to be destroyed through ion bombardment so that the first edge region 03 has no conductive channel, thereby reducing the gate leakage and improving the device reliability. However, since the second region 22 of the doped nitride semiconductor layer 20 is located in the second edge region 04, when ion bombardment is performed on the epitaxial structure 10, if the vertical projection of the second region 22 on the barrier layer 14 coincides with the vertical projection of the protective layer 70 on the barrier layer 14 or the vertical projection of the protective layer 70 on the barrier layer 14 is located within the vertical projection of the second region 22 on the barrier layer 14, the second region 22 of the doped nitride semiconductor layer 20 may be damaged, which causes the failure in pinching off the channel below the doped nitride semiconductor layer 20 when the device is turned off, and further causes the device leakage.

In S160, the epitaxial structure is processed such that the first edge region of the epitaxial structure is an electrically isolated region and a distance between an edge of a conductive channel of the second edge region and a vertical projection of the edge of the second region of the doped nitride semiconductor layer on the barrier layer is greater than a first preset value.

Referring to FIGS. 1-2 and 9-10, after the protective layer 70 is formed, ion bombardment may be performed on the epitaxial structure 10, and electrons of the first edge region 03 need to be destroyed through ion bombardment so that the first edge region 03 has no conductive channel 18 and the first edge region 03 of the epitaxial structure 10 is electrically isolated, thereby reducing the gate leakage and improving the device reliability.

In the example of the present application, before ion bombardment is performed on the edge region 02, the protective layer 70 is disposed to protect the doped nitride semiconductor layer 20 of the edge region 02. The vertical projection of the second region 22 of the doped nitride semiconductor layer 20 on the epitaxial structure 10 is located within the vertical projection of the protective layer 70 on the epitaxial structure 10, and the distance D2 between the vertical projection of the edge of the doped nitride semiconductor layer 20 on the epitaxial structure 10 and the vertical projection of the edge of the protective layer 70 on the epitaxial structure 10 is greater than the second preset value, which may be expressed as follows: the vertical projection of the protective layer 70 on the edge region 02 and the vertical projection of the second region 22 of the doped nitride semiconductor layer 20 on the edge region 02 have the same shape, the area of the vertical projection of the protective layer 70 on the edge region 02 is greater than the area of the vertical projection of the second region 22 of the doped nitride semiconductor layer 20 on the edge region 02, vertical projections of all edges of the protective layer 70 on the edge region 02 do not overlap vertical projections of all edges of the second region 22 of the doped nitride semiconductor layer 20 on the edge region 02, the distance between the vertical projection of an edge of the doped nitride semiconductor layer 20 on the epitaxial structure 10 and the vertical projection of the corresponding edge of the protective layer 70 on the epitaxial structure 10 is greater than the second preset value. For example, the second preset value may be greater than 25 nm so that the protective layer 70 can fully cover the doped nitride semiconductor layer 20. Since the vertical projection of the protective layer 70 on the edge region of the epitaxial structure 10 coincides with the second edge region 04, the distance D1 between the edge of the conductive channel 18 of the second edge region 04 and the vertical projection of the edge of the second region 22 of the doped nitride semiconductor layer 20 on the barrier layer 14 is greater than the first preset value. In this manner, when the edge region 02 is processed to form the electrically isolated region in the first edge region 03, the doped nitride semiconductor layer 20 can be prevented from being damaged and from being bombarded by ions, thereby reducing the gate leakage and improving the device reliability.

In S170, the protective layer is removed.

The protective layer 70 in FIG. 9 is removed to form the structure in FIG. 1. The protective layer 70 may be removed through wet etching, and the structures in FIGS. 1 and 2 are obtained after ion bombardment.

In the manufacturing method of a power device provided in the technical solution of the example of the present application, the vertical projection of the second region 22 on the barrier layer 14 is located in the conductive channel 18 of the second edge region 04, and the distance D1 between the vertical projection of the edge of the second region 22 on the barrier layer 14 and the edge of the conductive channel 18 of the second edge region 04 is greater than the first preset value. In this manner, the doped nitride semiconductor layer 20 can be prevented from being damaged when the electrically isolated region is formed in the first edge region 03, thereby reducing the gate leakage and improving the device reliability.

In one or more examples, referring to FIGS. 1 and 9, the first preset value is greater than 25 nm, and the second preset value is greater than 25 nm.

The first preset value is the same as the second preset value. If the first preset value is less than or equal to 25 nm, the process is challenging, and if the distance between the vertical projection of the edge of the second region 22 on the barrier layer 14 and the edge of the conductive channel 18 of the second edge region 04 is too small, the second region 22 of the doped nitride semiconductor layer 20 may be damaged when ion bombardment is performed on the edge region 02, resulting in the device leakage. Therefore, the first preset value is set to be greater than 25 nm, the second preset value is set to be greater than 25 nm, and in the width direction Y of the doped nitride semiconductor layer 20, the width of the second edge region 04 is at least 50 nm greater than the width of the doped nitride semiconductor layer 20. When the edge region 02 is processed, the second region 22 of the doped nitride semiconductor layer 20 is not damaged, thereby reducing the gate leakage and improving the device reliability.

In one or more examples, S150 may be refined on the basis of the preceding examples. The step S150 in which the protective layer is formed on the side of the passivation layer facing away from the epitaxial structure specifically includes the following: in S151, a protective material layer is formed on the side of the passivation layer facing away from the epitaxial structure; and in S152, patterned etching is performed on the protective material layer to form the protective layer.

Specifically, the examples of the present application provide a manufacturing method of a power device, which specifically includes the steps described below.

In S110, an epitaxial structure is formed. The epitaxial structure includes a substrate, a buffer layer, a channel layer, and a barrier layer that are stacked in sequence, and the epitaxial structure includes an active region and an edge region, and the edge region surrounds the active region and includes a first edge region and a second edge region.

In S120, a doped nitride semiconductor layer is formed on one side of the epitaxial structure. The doped nitride semiconductor layer includes a first region and a second region that are connected to each other, the first region covers a portion of the active region of the epitaxial structure, and a vertical projection of the second region on the barrier layer is located in the second edge region.

In S130, a passivation layer is formed on the side of the doped nitride semiconductor layer facing away from the epitaxial structure. The passivation layer includes a first trench and a second trench, a vertical projection of the first trench on the epitaxial structure overlaps the active region, and a vertical projection of the second trench on the epitaxial structure overlaps the active region.

In S140, a source is formed in the first trench, and a drain is formed in the second trench.

In S151, a protective material layer is formed on the side of the passivation layer facing away from the epitaxial structure.

The material of the protective material layer may include photoresist or titanium. The protective material layer is formed on the side of the passivation layer facing away from the epitaxial structure, and a vertical projection of the protective material layer on the epitaxial structure covers the active region and the edge region of the epitaxial structure.

In S152, patterned etching is performed on the protective material layer to form a protective layer.

Patterned etching is performed on the protective material layer to form the protective layer, and the vertical projection of the protective layer on the epitaxial structure covers the active region and the second edge region of the epitaxial structure. In this manner, the doped nitride semiconductor layer can be prevented from being damaged when the epitaxial structure is processed, thereby reducing the gate leakage and improving the device reliability.

In S160, the epitaxial structure is processed such that the first edge region of the epitaxial structure is an electrically isolated region and a distance between an edge of a conductive channel 18 of the second edge region and a vertical projection of the edge of the second region of the doped nitride semiconductor layer on the barrier layer is greater than a first preset value.

In S170, the protective layer is removed.

In one or more examples, S120 may be refined on the basis of the preceding examples. The step S120 in which the doped nitride semiconductor layer is formed on the side of the barrier layer facing away from the substrate specifically includes the following: in S121, a doped nitride semiconductor material layer is formed on a side of the epitaxial structure; and in S122, patterned etching is performed on the doped nitride semiconductor material layer to form the doped nitride semiconductor layer; where the shape of the vertical projection of the doped nitride semiconductor layer on the epitaxial structure is a ring.

Specifically, the examples of the present application provide a manufacturing method of a power device, which specifically includes the following:

In S110, an epitaxial structure is formed. The epitaxial structure includes a substrate, a buffer layer, a channel layer and a barrier layer that are stacked in sequence, the epitaxial structure includes an active region and an edge region, the edge region surrounds the active region and includes a first edge region and a second edge region, and a conductive channel is provided at the interface between the channel layer and the barrier layer in the second edge region.

In S121, a doped nitride semiconductor material layer is formed on one side of the epitaxial structure.

Referring to FIG. 4, the doped nitride semiconductor material layer 23 is formed on one side of the epitaxial structure 10 through a deposition process.

In S122, patterned etching is performed on the doped nitride semiconductor material layer to form a doped nitride semiconductor layer. The shape of the vertical projection of the doped nitride semiconductor layer on the epitaxial structure is a ring.

Referring to FIG. 5, patterned etching is performed on the doped nitride semiconductor material layer 23 to form the doped nitride semiconductor layer 20, and the shape of the vertical projection of the doped nitride semiconductor layer on the epitaxial structure is the ring. For example, referring to FIG. 1, the shape of the vertical projection of the doped nitride semiconductor layer 20 on the epitaxial structure 10 is the ring, and the ring-shaped nitride semiconductor layer 20 surrounds the source 50 so that concentration of the electric field can be alleviated, the voltage withstand capability of the device can be improved, the capability to control the channel can be enhanced and the device performance can be improved, thereby improving the device stability and reliability.

In S130, a passivation layer is formed on the side of the doped nitride semiconductor layer facing away from the epitaxial structure. The passivation layer includes a first trench and a second trench, a vertical projection of the first trench on the epitaxial structure overlaps the active region, and a vertical projection of the second trench on the epitaxial structure overlaps the active region.

In S140, a source is formed in the first trench, and a drain is formed in the second trench.

In S150, a protective layer is formed on the side of the passivation layer facing away from the epitaxial structure. The vertical projection of the protective layer on the epitaxial structure covers the active region of the epitaxial structure, a vertical projection of the protective layer on the edge region of the epitaxial structure coincides with the second edge region, and a distance between a vertical projection of an edge of a second region of the doped nitride semiconductor layer on the epitaxial structure and a vertical projection of an edge of the protective layer on the epitaxial structure is greater than a second preset value.

In S160, the epitaxial structure is processed such that the edge region of the epitaxial structure is an electrically isolated region and a distance between an edge of a conductive channel of the second edge region and a vertical projection of the edge of the second region of the doped nitride semiconductor layer on the barrier layer is greater than a first preset value.

In S170, the protective layer is removed.

In one or more examples, the step S130 in which the passivation layer is formed on the side of the doped nitride semiconductor layer facing away from the epitaxial structure includes the following:

In S131, the passivation layer is formed on the side of the doped nitride semiconductor layer facing away from the epitaxial structure. The passivation layer covers the doped nitride semiconductor layer and a portion of the epitaxial structure not covered by the doped nitride semiconductor layer.

The passivation layer may be formed on the side of the doped nitride semiconductor layer facing away from the epitaxial structure through a deposition process.

In S132, the passivation layer is etched to form a first trench and a second trench. A vertical projection of the first trench on the epitaxial structure is located within the central region of the ring, and a vertical projection of the second trench on the epitaxial structure is located at a side of the ring.

Referring to FIGS. 9 and 10, the vertical projection of the first trench 41 on the epitaxial structure 10 is located within the central region of the ring, that is, when the source 50 is prepared in the first trench 41 subsequently, the doped nitride semiconductor layer 20 surrounds the source 50 so that concentration of the electric field can be alleviated, the voltage withstand capability of the device can be improved, the capability to control the channel can be enhanced and the device performance can be improved, thereby improving the device stability and reliability. The vertical projection of the second trench 42 on the epitaxial structure is located at one side of the ring, and the drain 60 is prepared in the second trench 42 subsequently, thereby enabling the device to be turned on.

The examples of the present application provide a manufacturing method of a power device on the basis of the preceding examples. The manufacturing method includes the following:

In S110, an epitaxial structure is formed. The epitaxial structure includes a substrate, a buffer layer, a channel layer and a barrier layer that are stacked in sequence, the epitaxial structure includes an active region and an edge region, the edge region surrounds the active region and includes a first edge region and a second edge region, and a conductive channel is provided at the interface between the channel layer and the barrier layer in the second edge region.

In S120, a doped nitride semiconductor layer is formed on one side of the epitaxial structure. The doped nitride semiconductor layer includes a first region and a second region that are connected to each other, the first region covers a portion of the active region of the epitaxial structure, and a vertical projection of the second region on the barrier layer is located in the second edge region.

In S210, a gate is formed on a side of the doped nitride semiconductor layer facing away from the epitaxial structure. The gate covers at least a portion of the doped nitride semiconductor layer.

Referring to FIG. 5, the gate 30 is formed on the side of the doped nitride semiconductor layer 20 facing away from the epitaxial structure 10 and covers at least a portion of the doped nitride semiconductor layer 20 so that the vertical projection of the gate 30 on the epitaxial structure 10 is located within the vertical projection of the doped nitride semiconductor layer 20 on the epitaxial structure 10, thereby reducing the leakage of the gate 30 and improving the device reliability. Through the adjustment of a gate voltage, the doped nitride semiconductor layer 20 can change the distribution of the electric field of the two-dimensional electron gas in the conductive channel 18 to improve the voltage withstand capability of the device, and the electron concentration of the two-dimensional electron gas can be accurately controlled to enhance the capability of the device to control the current.

In S130, a passivation layer is formed on the side of the gate facing away from the epitaxial structure. The passivation layer includes a first trench and a second trench, a vertical projection of the first trench on the epitaxial structure overlaps the active region, and a vertical projection of the second trench on the epitaxial structure overlaps the active region.

In S140, a source is formed in the first trench, and a drain is formed in the second trench.

In S150, a protective layer is formed on the side of the passivation layer facing away from the epitaxial structure. A vertical projection of the protective layer on the epitaxial structure covers the active region of the epitaxial structure, a vertical projection of the protective layer on the edge region of the epitaxial structure coincides with the second edge region, and a distance between a vertical projection of an edge of the second region of the doped nitride semiconductor layer on the epitaxial structure and a vertical projection of an edge of the protective layer on the epitaxial structure is greater than a second preset value.

In S160, the epitaxial structure is processed such that the first edge region of the epitaxial structure is an electrically isolated region and a distance between an edge of a conductive channel of the second edge region and a vertical projection of the edge of the second region of the doped nitride semiconductor layer on the barrier layer is greater than a first preset value.

In one or more examples, processing the epitaxial structure such that the first edge region of the epitaxial structure is the electrically isolated region includes performing ion bombardment on the epitaxial structure such that the first edge region of the epitaxial structure is the electrically isolated region.

Ion bombardment is performed on the epitaxial structure, and the ion energy for the ion bombardment may be set as needed such that the first edge region of the epitaxial structure is the electrically isolated region, thereby reducing the gate leakage and improving the device reliability.

In one or more examples, an ion source for the ion bombardment is at least one of nitrogen, fluorine, oxygen, or argon.

The ion source for the ion bombardment is at least one of nitrogen, fluorine, oxygen or argon. Nitrogen, fluorine, oxygen, and argon are all heavy atoms. Setting the ion source to at least one of nitrogen, fluorine, oxygen, and argon can destroy electrons of the edge region so that no conductive channel exists outside the active region and the edge region of the epitaxial structure is an electrically isolated region, thereby reducing the gate leakage and improving the device reliability.

The manufacturing methods of the power device provided in the examples of the present application have the same beneficial effects as the power device in any example of the present application.

It is to be understood that various forms of the preceding flows may be used with steps reordered, added, or deleted. For example, the steps described in the present application may be executed in parallel, in sequence, or in a different order, as long as the desired results of the technical solutions of the present application can be achieved. The execution sequence of the steps is not limited herein.

The preceding examples are not intended to limit the scope of the present application. It is to be understood by those skilled in the art that various modifications, combinations, subcombinations, and substitutions may be made according to design requirements and other factors. Any modifications, equivalent substitutions, and improvements that are made within the spirit and principle of the present application are within the scope of the present application.

What is claimed is:

1. A power device, comprising:
an epitaxial structure, wherein the epitaxial structure comprises a substrate, a buffer layer, a channel layer and a barrier layer that are stacked in sequence, and the epitaxial structure comprises an active region and an edge region, wherein the edge region surrounds the active region and comprises a first edge region and a second edge region, the first edge region of the epitaxial structure is an electrically isolated region, and a conductive channel is provided at an interface between the channel layer and the barrier layer in the second edge region;
a doped nitride semiconductor layer located on a side of the barrier layer facing away from the substrate, wherein the doped nitride semiconductor layer comprises a first region and a second region connected to each other, the first region covers a portion of the active region of the epitaxial structure, a vertical projection of the second region on the barrier layer is located in the conductive channel of the second edge region, and a distance between an edge of the conductive channel of the second edge region and a vertical projection of an edge of the second region on the barrier layer is greater than a first preset value;
a passivation layer located on a side of the doped nitride semiconductor layer facing away from the epitaxial structure, wherein the passivation layer comprises a first trench and a second trench, a vertical projection of the first trench on the epitaxial structure overlaps the active region, and a vertical projection of the second trench on the epitaxial structure overlaps the active region; and
a source located in the first trench and a drain located in the second trench.

2. The power device according to claim 1, wherein the first preset value is greater than 25 nm.

3. The power device according to claim 1, wherein a shape of a vertical projection of the doped nitride semiconductor layer on the epitaxial structure is a ring; and
the vertical projection of the first trench on the epitaxial structure is located within a central region of the ring, and the vertical projection of the second trench on the epitaxial structure is located at a side of the ring.

4. The power device according to claim 1, further comprising:
a gate located on the side of the doped nitride semiconductor layer facing away from the epitaxial structure, wherein the gate covers at least a portion of the doped nitride semiconductor layer.

5. The power device according to claim 1, wherein the doped nitride semiconductor layer comprises a p-type GaN layer or a p-type AlGaN layer.

6. A manufacturing method of a power device, comprising:
forming an epitaxial structure, wherein the epitaxial structure comprises a substrate, a buffer layer, a channel layer and a barrier layer that are stacked in sequence, the epitaxial structure comprises an active region and an edge region, and the edge region surrounds the active region and comprises a first edge region and a second edge region;
forming a doped nitride semiconductor layer on a side of the barrier layer facing away from the substrate, wherein the doped nitride semiconductor layer comprises a first region and a second region connected to each other, the first region covers a portion of the active region of the epitaxial structure, and a vertical projection of the second region on the barrier layer is located in the second edge region;
forming a passivation layer on a side of the doped nitride semiconductor layer facing away from the epitaxial structure, wherein the passivation layer comprises a first trench and a second trench, a vertical projection of the first trench on the epitaxial structure overlaps the active region, and a vertical projection of the second trench on the epitaxial structure overlaps the active region; forming a source in the first trench, and forming a drain in the second trench;
forming a protective layer on a side of the passivation layer facing away from the epitaxial structure, wherein a vertical projection of the protective layer on the epitaxial structure covers the active region of the epitaxial structure, a vertical projection of the protective layer on the edge region of the epitaxial structure coincides with the second edge region, and a distance between a vertical projection of an edge of the second region of the doped nitride semiconductor layer on the epitaxial structure and a vertical projection of a respective edge of the protective layer corresponding to the edge of the second region on the epitaxial structure is greater than a second preset value;
processing the epitaxial structure such that the first edge region of the epitaxial structure is an electrically isolated region and a distance between an edge of a conductive channel of the second edge region and a vertical projection of the edge of the second region of the doped nitride semiconductor layer on the barrier layer is greater than a first preset value; and
removing the protective layer.

7. The manufacturing method of the power device according to claim 6, wherein the first preset value is greater than 25 nm, and the second preset value is greater than 25 nm.

8. The manufacturing method of the power device according to claim 6, wherein forming the protective layer on the side of the passivation layer facing away from the epitaxial structure comprises:
forming a protective material layer on the side of the passivation layer facing away from the epitaxial structure; and
performing patterned etching on the protective material layer to form the protective layer.

9. The manufacturing method of the power device according to claim 6, wherein forming the doped nitride semiconductor layer on the side of the barrier layer facing away from the substrate comprises:
forming a doped nitride semiconductor material layer on one side of the epitaxial structure; and
performing patterned etching on the doped nitride semiconductor material layer to form the doped nitride semiconductor layer, wherein a shape of a vertical projection of the doped nitride semiconductor layer on the epitaxial structure is a ring.

10. The manufacturing method of the power device according to claim 9, wherein forming the passivation layer on the side of the doped nitride semiconductor layer facing away from the epitaxial structure comprises:
forming the passivation layer on the side of the doped nitride semiconductor layer facing away from the epitaxial structure, wherein the passivation layer covers the doped nitride semiconductor layer and a portion of the epitaxial structure which is not covered by the doped nitride semiconductor layer; and
etching the passivation layer to form the first trench and the second trench, wherein the vertical projection of the first trench on the epitaxial structure is located within a central region of the ring, and the vertical projection of the second trench on the epitaxial structure is located at a side of the ring.

11. The manufacturing method of the power device according to claim 6, wherein after forming the doped nitride semiconductor layer on the side of the barrier layer facing away from the substrate, the method further comprises:
forming a gate on the side of the doped nitride semiconductor layer facing away from the epitaxial structure, wherein the gate covers at least a portion of the doped nitride semiconductor layer.

12. The manufacturing method of the power device according to claim 6, wherein processing the epitaxial structure such that the first edge region of the epitaxial structure is the electrically isolated region comprises:
performing ion bombardment on the epitaxial structure such that the first edge region of the epitaxial structure is the electrically isolated region.

13. The manufacturing method of the power device according to claim 12, wherein an ion source for the ion bombardment is at least one of nitrogen, fluorine, oxygen, or argon.
